(19) United States
(12) Patent Application Publication
(10) Pub. No.: US 2026/0005021 A1
(43) Pub. Date: Jan. 1, 2026

(54) FACET TRAPPING FOR EPITAXIAL GROWTH

(71) Applicant: TEXAS INSTRUMENTS INCORPORATED, Dallas, TX (US)

(72) Inventors: Samuel Langer, Lehi, UT (US); Kenneth James Bogedahl, Lehi, UT (US); Ian C. Laboriante, Lehi, UT (US); Matthew Willford, Lehi, UT (US); Stephen McNary, Provo, UT (US); Gregg Rawlings, American Fork, UT (US); Gordon Nielsen, Cedar Hills, UT (US)

(21) Appl. No.: 18/757,075

(22) Filed: Jun. 27, 2024

(51) Int. Cl. H01L 21/02; H01L 21/311; H01L 29/06; H01L 29/732

(52) U.S. Cl. CPC H01L 21/02639; H01L 21/02694; H01L 21/31111; H10D 10/441; H10D 62/124

(57) ABSTRACT

The present disclosure generally relates to semiconductor processing including facet trapping for an epitaxial growth process. In an example, a semiconductor device includes a first semiconductor material, a dielectric layer, and a second semiconductor material. The first semiconductor material includes a monocrystalline surface. The dielectric layer is over the first semiconductor material. The dielectric layer has an opening to the monocrystalline surface. The opening is defined at least in part by a sidewall of the dielectric layer and a cavity in the dielectric layer. The cavity is at the monocrystalline surface and under the sidewall. The second semiconductor material is over the first semiconductor material and on the monocrystalline surface. The second semiconductor material is at least partially in the opening through the dielectric layer. The cavity in the dielectric layer is configured to trap a facet of the second semiconductor material in the cavity.

### BACKGROUND

Integrated circuits may include bipolar junction transistors (BJTs). BJTs may be desirable for their high gain characteristics to satisfy high performance and high current drive needs. Scaling of devices in an integrated circuit to smaller nodes typically requires novel approaches to semiconductor processing for fabricating those devices.

### SUMMARY

An example described herein is a semiconductor device. The semiconductor device includes a first semiconductor material, a dielectric layer, and a second semiconductor material. The first semiconductor material includes a monocrystalline surface. The dielectric layer is over the first semiconductor material. The dielectric layer has an opening to the monocrystalline surface. The opening is defined at least in part by a sidewall of the dielectric layer and a cavity in the dielectric layer. The cavity is at the monocrystalline surface and under the sidewall. The second semiconductor material is over the first semiconductor material and on the monocrystalline surface. The second semiconductor material is at least partially in the opening through the dielectric layer. The cavity in the dielectric layer is configured to trap a facet of the second semiconductor material in the cavity.

Another example is a method. A dielectric layer is formed over a first semiconductor material. The first semiconductor material includes a monocrystalline surface. An opening is formed through the dielectric layer to the monocrystalline surface. The opening is defined at least in part by a sidewall of the dielectric layer and a cavity in the dielectric layer. The cavity is at the monocrystalline surface and under the sidewall. A second semiconductor material is over the first semiconductor material and on the monocrystalline surface. The second semiconductor material is at least partially in the opening through the dielectric layer. The cavity in the dielectric layer is configured to trap a facet of the second semiconductor material in the cavity.

A further example is a semiconductor device. The semiconductor device includes a semiconductor substrate, a pedestal dielectric structure, a collector layer, a base layer, and an emitter layer. The semiconductor substrate has an upper surface. The pedestal dielectric structure is over the semiconductor substrate. The pedestal dielectric structure has an opening to the upper surface of the semiconductor substrate. The opening is defined at least in part by a sidewall of the pedestal dielectric structure and a cavity in the pedestal dielectric structure. The cavity is at the upper surface and under the sidewall. The cavity has a surface that meets the sidewall at a first intersection and meets the upper surface at a second intersection. A vertical dimension is vertically from the upper surface to the first intersection. A lateral dimension is laterally from the first intersection to the second intersection. A ratio of the vertical dimension to the lateral dimension is equal to or less than 1.376. The collector layer is on the upper surface of the semiconductor substrate and at least partially in the opening through the pedestal dielectric structure. The base layer is on the collector layer. The emitter layer is on the base layer.

The foregoing summary outlines rather broadly various features of examples of the present disclosure in order that the following detailed description may be better understood. Various features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIGS. 1 through 7 are respective cross-sectional views of a semiconductor structure in intermediate stages of manufacturing according to some examples.

FIGS. 8 through 27 are respective cross-sectional views of a semiconductor device in intermediate stages of manufacturing according to some examples.

FIGS. 12A, 13A, 14A, 15A, and 16A are expanded views of portions of the cross-sectional views of FIGS. 12, 13, 14, 15, and 16, respectively.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. Other examples may include any permutation of including or excluding aspects or features that are described. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates generally, but not exclusively, to semiconductor processing including facet trapping for an epitaxial growth process. Some examples include a semiconductor device that include a first semiconductor material, a dielectric layer, and a second semiconductor material. The first semiconductor material includes a monocrystalline surface. The dielectric layer is over the first semiconductor material and has an opening to the monocrystalline surface. The opening through the dielectric layer is defined at least in part by a sidewall of the dielectric layer and a cavity in the dielectric layer. The cavity is at the monocrystalline surface of the first semiconductor material and is under the sidewall of the dielectric layer. The second semiconductor material is over the first semiconductor material and is on the monocrystalline surface of the first semiconductor material. The second semiconductor material is at least partially in the opening through the dielectric layer. The second semiconductor material may be formed using epitaxial growth. During epitaxial growth of the second semiconductor material, a facet may be formed by the second semiconductor material. The cavity in the dielectric layer may be configured in a way that the facet is trapped by the cavity such that propagation of the facet during subsequent epitaxial grown is arrested. Arresting propagation of the facet may permit a plane of the monocrystalline surface to more easily be replicated in the second semiconductor material. Other benefits and advantages may be achieved.

Various examples are described subsequently. Although the specific examples may illustrate various aspects of the above generally described features, examples may incorporate any combination of the above generally described features (which are described in more detail in examples below).

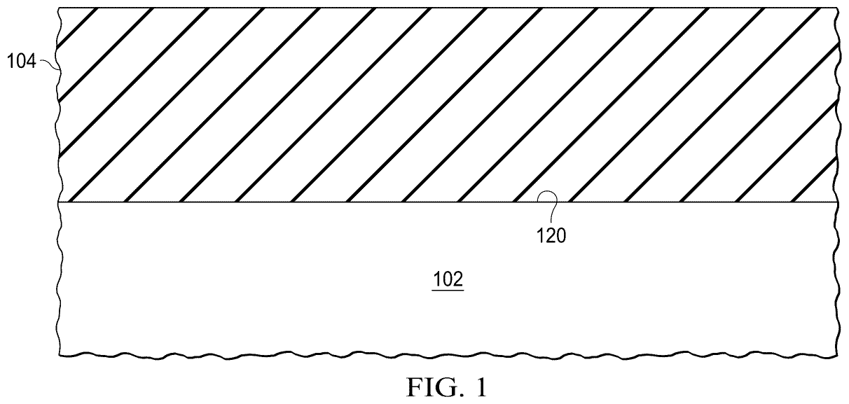

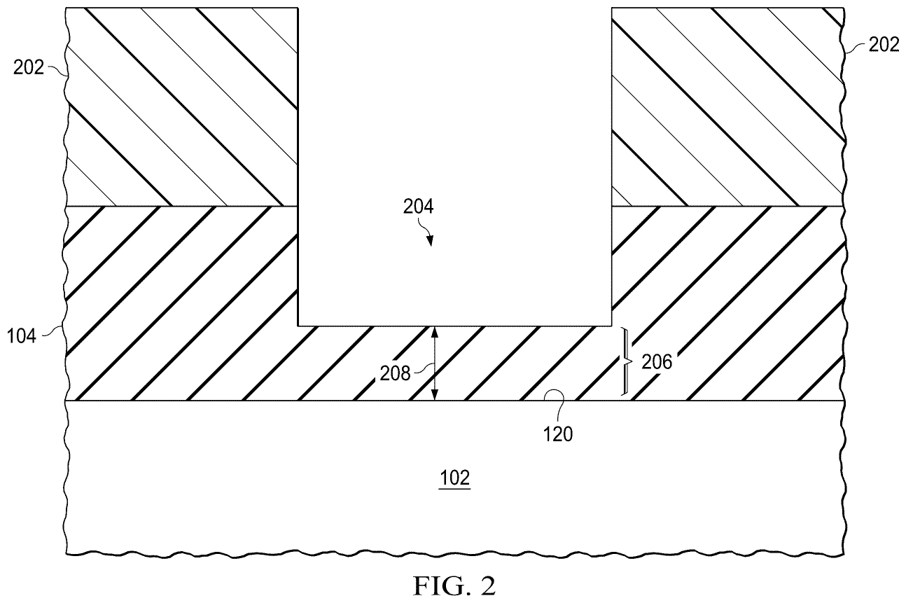

FIGS. 1 through 7 are respective cross-sectional views of a semiconductor structure in intermediate stages of manufacturing according to some examples. Referring to FIG. 1, a dielectric layer 104 is formed over a semiconductor substrate 102. The semiconductor substrate 102 includes a semiconductor material that is monocrystalline. The semiconductor substrate 102 has an upper surface 120 that is a monocrystalline surface of the monocrystalline semiconductor material. The semiconductor substrate 102 may be or include a bulk semiconductor substrate, a semiconductor-on-insulator (SOI) substrate, or any other appropriate substrate. The semiconductor substrate 102 may also include a support (or handle) substrate and an epitaxial layer epitaxially grown on the support substrate. In some examples, the semiconductor substrate 102 is or includes a silicon substrate (which may be singulated from a bulk silicon wafer at the conclusion of semiconductor processing). In further examples, the semiconductor substrate 102 includes a silicon substrate with an epitaxial silicon layer grown thereon. In some examples, the semiconductor material is or includes silicon (Si), silicon germanium (SiGe), gallium arsenide (GaAs), gallium nitride (GaN), the like, or a combination thereof. In some examples, the monocrystalline semiconductor material is silicon, and the upper surface 120 is a (100) plane of monocrystalline silicon.

The dielectric layer 104 may be or include one dielectric layer or multiple dielectric sub-layers. For example, the dielectric layer 104 may be or include silicon oxide. In some examples, the dielectric layer 104 is silicon oxide formed by in situ steam generation (ISSG) oxidation. In some examples, the dielectric layer 104 is silicon oxide (e.g., a tetraethyl orthosilicate (TEOS) oxide) deposited by chemical vapor deposition (CVD). In some examples, the dielectric layer 104 includes a first sub-layer of a silicon oxide (e.g., silicon oxide formed by ISSG oxidation) and a second sub-layer of silicon oxide (e.g., a TEOS oxide deposited by CVD) over the first sub-layer. In such examples, the first sub-layer has a first etch rate, and the second sub-layer has a second etch rate greater than the first etch rate. In other examples, the dielectric layer 104 may be or include different dielectric materials, such as silicon nitride, silicon oxynitride, silicon carbon nitride, the like, or a combination thereof.

Referring to FIG. 2, a photoresist 202 is formed over the dielectric layer 104 and patterned with an opening through the photoresist 202. For example, the photoresist 202 is deposited (e.g., by spin-on) over and/or on the dielectric layer 104 and is patterned to have the opening using photolithography. Then, a recess 204 is formed in the dielectric layer 104 through the opening of the photoresist 202. Using the patterned photoresist 202 as a mask, an etch process, such as an anisotropic etch like a reactive ion etch (RIE) or the like, is performed to etch the dielectric layer 104 and form the recess 204 in the dielectric layer 104. The recess 204 is defined by substantially vertical sidewalls and a bottom surface formed by a lateral surface of the dielectric layer 104. A portion 206 of the dielectric layer 104 remains between the recess 204 (e.g., from the bottom surface of the recess 204) and the upper surface 120 of the semiconductor substrate 102. The portion 206 of the dielectric layer 104 has a thickness 208 (e.g., from the bottom surface of the recess 204 to the upper surface 120 of the semiconductor substrate 102). The thickness 208 subsequently defines, at least in part, a dimension of a facet trap (e.g., a cavity) formed in the dielectric layer 104. The thickness 208 may be achieved by tuning the duration of the etch process that forms the recess 204, by an etch selectivity between different sub-layers of the dielectric layer 104, and/or by another mechanism.

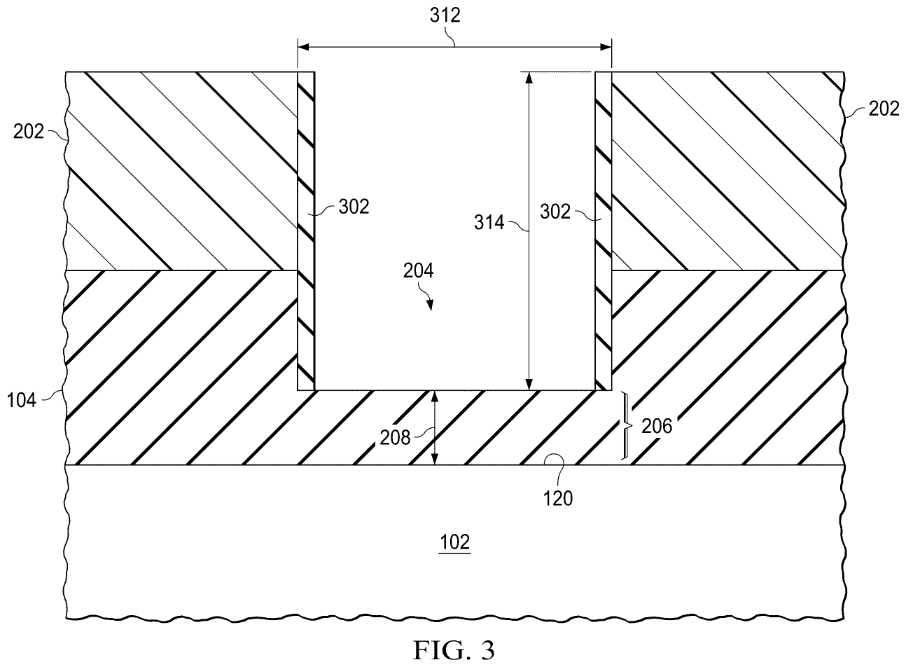

Referring to FIG. 3, sidewall etch stop liners 302 are formed along respective sidewalls of the recess 204 in the dielectric layer 104. In some examples, the sidewall etch stop liners 302 are polymer liners. In some examples in which the sidewall etch stop liners 302 are polymer liners, the sidewall etch stop liners 302 may be deposited along the sidewalls of the recess 204 by flowing a gas including difluoromethane (CH₂F₂), fluoromethane (CH₃F), methane (CH₄), octafluorocyclobutane (C₄F₈), hexafluorobutadiene (C₄F₆), the like, or a combination thereof in a plasma. In some examples, the gas may include oxygen (O₂), which may control a deposition rate of a polymer along the sidewalls. Polymer liners may be hydrophobic. In some examples, polymer liners may have low removability in a low temperature plasma and in a buffered oxide etch (BOE).

In some examples in which the sidewall etch stop liners 302 are polymer liners, the polymer liners may be deposited along the sidewalls of the recess 204 without depositing a polymer liner on the bottom surface of the recess 204. The aspect ratio of the combined recess 204 in the dielectric layer 104 and corresponding opening through the photoresist 202 may be a sufficient size to prevent a polymer liner from being deposited on the bottom surface of the recess 204 while allowing sufficient coverage of the polymer liners along the sidewalls of the recess 204. The aspect ratio, in this example, is a ratio of the lateral width 312 of the recess 204 (which corresponds to the width of the opening through the photoresist 202) to the vertical depth 314 of the recess 204 from a top surface of the photoresist 202 (e.g., from the top surface of the photoresist 202 to the bottom surface of the recess 204). The thickness of the photoresist 202 may be tuned and/or one or more sacrificial layers may be formed between the dielectric layer 104 and the photoresist 202 to achieve a target aspect ratio.

In some examples in which the sidewall etch stop liners 302 are polymer liners, polymer liners may be deposited along the sidewalls and the bottom surface of the recess 204. In such examples, an anisotropic etch (e.g., an RIE) may be performed to remove any polymer liner from the bottom surface of the recess 204 while the polymer liners remain on the sidewalls of the recess 204. Similarly, when the sidewall etch stop liners 302 are other materials, such as silicon nitride conformally deposited by atomic layer deposition (ALD) or the like, an anisotropic etch may be performed to remove the liner from the bottom surface of the recess 204.

In some examples, the etch process to form the recess 204, the deposition of the sidewall etch stop liners 302, and where applicable, the subsequent etch process to remove a liner from the bottom surface of the recess 204 is performed in a same processing chamber. The processing chamber may be an inductively coupled plasma (ICP) chamber or a capacitively coupled plasma (CCP) chamber. The semiconductor substrate 102 (with the dielectric layer 104 and patterned photoresist 202) is transferred into the processing chamber. While in the processing chamber, the anisotropic etch (e.g., an RIE) is performed to etch the dielectric layer 104 anisotropically through the opening through the photoresist 202 to form the recess 204. Following the anisotropic etch, a plasma is generated by the processing chamber, and a gas is flowed into the processing chamber (with the plasma therein) to deposit polymer liners on the sidewalls of the recess 204. Following the deposition of polymer liners, another anisotropic etch (e.g., an RIE) may optionally be performed in the processing chamber to remove any polymer liner on a bottom surface of the recess 204. Thereafter, the semiconductor substrate 102 may then be transferred out of the processing chamber.

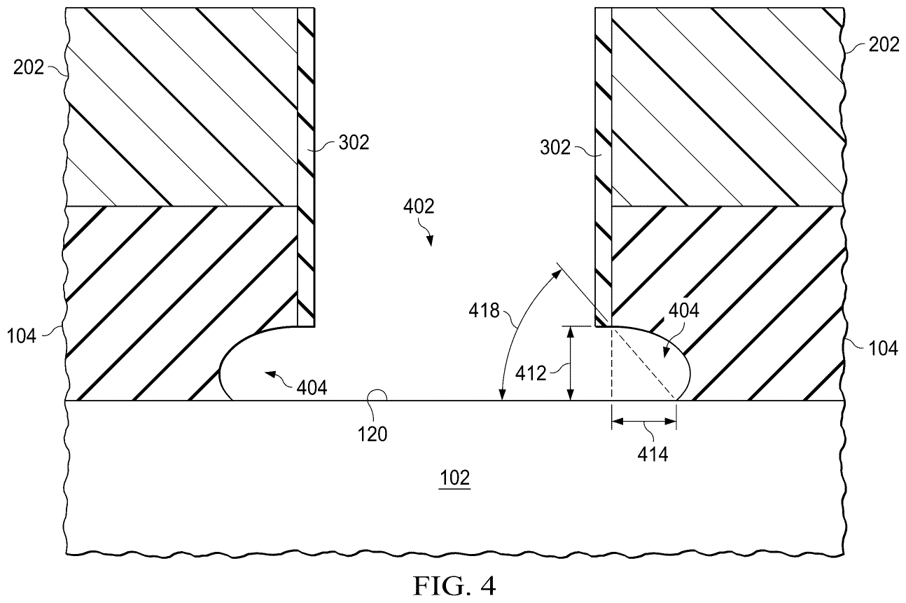

Referring to FIG. 4, an etch is performed to remove the remaining portion 206 of the dielectric layer 104 and to undercut in the dielectric layer 104 under the sidewall etch stop liners 302. The etch may be an isotropic etch, which may further be a wet etch. The etch is selective to the material of the dielectric layer 104. For example, when the dielectric layer 104 is silicon oxide, the etch process may be or include a buffered oxide etch (BOE), a dilute hydrofluoric (dHF) acid, or the like. The sidewall etch stop liners 302 prevent the sidewalls of the dielectric layer 104 from being etched where the sidewall etch stop liners 302 cover the sidewalls. The etch removes the remaining portion 206 of the dielectric layer 104 in a direction from the bottom surface of the recess 204 to expose the upper surface 120 of the semiconductor substrate 102. As the etch is performed, cavities 404 are isotropically formed in the dielectric layer 104 undercutting the sidewall etch stop liners 302. The cavities 404 are formed to and expose the upper surface 120 of the semiconductor substrate 102. The etch forms an opening 402 through the dielectric layer 104, and the opening 402 is laterally defined by the sidewall etch stop liners 302 and cavities 404. The cavities 404 may result in the opening 402 avoiding having lateral footings of the dielectric layer 104 at the upper surface 120 of the semiconductor substrate 102 that would laterally constrict the opening 402 more than the sidewalls of the opening 402. Avoiding such footings may remove a mechanism that induces or influences facet formation during subsequent epitaxial growth—e.g., on the exposed upper surface 120 of the semiconductor substrate 102.

A cavity 404, as illustrated, is defined by a curved surface of the dielectric layer 104. The cavity 404 has a vertical dimension 412 and a lateral dimension 414. The vertical dimension 412 is from the upper surface 120 of the semiconductor substrate 102 orthogonally to an intersection point where the curved surface of the cavity 404 meets the corresponding sidewall of the dielectric layer 104 (formed by the recess 204). The vertical dimension 412 may be equal to or greater than the thickness 208 of the remaining portion 206 of the dielectric layer 104 that is etched. The lateral dimension 414 is from the corresponding sidewall of the dielectric layer 104 (formed by the recess 204) orthogonally to an intersection point where the curved surface of the cavity 404 meets the upper surface 120 of the semiconductor substrate 102. The vertical dimension 412 and lateral dimension 414 form an angle 418 between the upper surface 120 of the semiconductor substrate 102 and a line from the intersection point where the curved surface of the cavity 404 meets the upper surface 120 to the intersection point where the curved surface of the cavity 404 meets the corresponding sidewall of the dielectric layer 104 (formed by the recess 204). The angle 418 is laterally interior to the opening 402. The angle 418 is the inverse tangent of the ratio of the vertical dimension 412 to the lateral dimension 414 (e.g., θ₄₁₈=tan⁻¹(v₄₁₂/L₄₁₄), where θ₄₁₈ is the angle 418, V₄₁₂ is the vertical dimension 412, and L₄₁₄ is the lateral dimension 414). In some examples, the lateral dimension 414 is equal to or greater than 10 nm, such as equal to or greater than 20 nm.

The angle 418 (and hence, the ratio of the vertical dimension 412 to the lateral dimension 414) is such that a facet formed in a subsequent epitaxial growth is trapped in the cavity 404. For example, when the upper surface 120 is a (100) plane of monocrystalline silicon and silicon is epitaxially grown on the upper surface 120, the silicon epitaxially grown may have a (111) plane facet. In such an example, the angle 418 may be equal to or less than 54.7° (e.g., equal to or less than 54°). The ratio of the vertical dimension 412 to the lateral dimension 414 may be equal to or less than 1.376. With such an angle 418, the (111) plane facet may intersect the curved surface of the cavity 404 when the silicon is grown to sufficient thickness, which may cause the (111) plane facet to arrest further propagation in subsequent epitaxial growth. Hence, the cavity 404 may be considered a facet trap. The angle 418 may be another angle depending on, e.g., which plane of a facet may be trapped by the cavity 404.

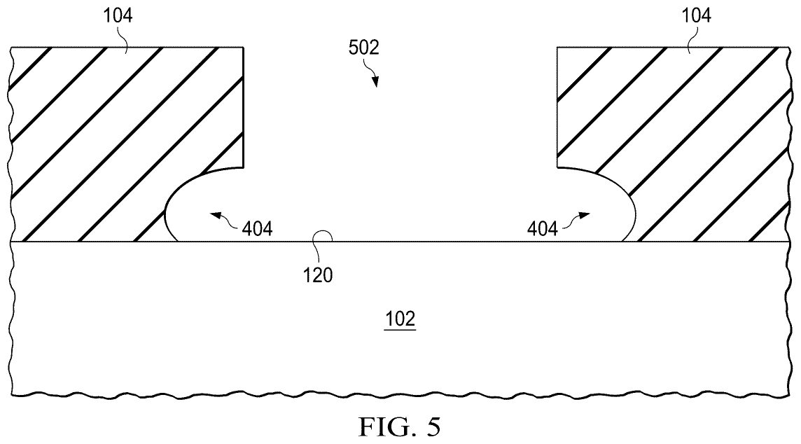

Referring to FIG. 5, the photoresist 202 and the sidewall etch stop liners 302 are removed. The removal of the photoresist 202 and the sidewall etch stop liners 302 result in an opening 502 through the dielectric layer 104. The opening 502 is defined by sidewalls of the dielectric layer 104 and curved surfaces of the cavities 404 in the dielectric layer 104. The upper surface 120 of the semiconductor substrate 102 is exposed through the opening 502. In some examples, such as where the sidewall etch stop liners 302 are polymer liners, the photoresist 202 and the sidewall etch stop liners 302 may be removed by a sulfuric acid (H₂SO₄) and hydrogen peroxide (H₂O₂) mixture (SPM) followed by a first step standard clean (SC1) of an RCA clean. Any appropriate wet process may be performed to remove the photoresist 202 and the sidewall etch stop liners 302 in other examples. A wet process, as opposed to a plasma process (e.g., ashing), may avoid plasma damage to the upper surface 120 of the semiconductor substrate 102.

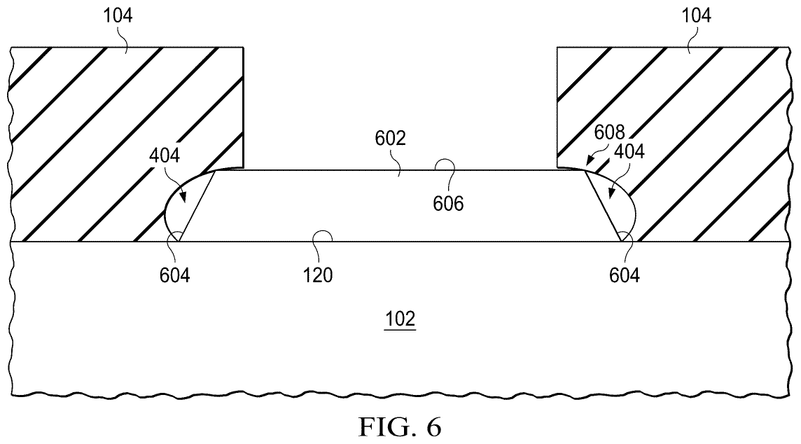

Referring to FIG. 6, an epitaxial layer 602 is epitaxially grown to a thickness sufficient such that a facet 604 of the epitaxial layer 602 is trapped in the cavity 404. The epitaxial layer 602 may be any semiconductor material and may be monocrystalline. In some examples, the epitaxial layer 602 is silicon. The epitaxial growth process may be a CVD process, such as a low pressure CVD (LPCVD), reduced pressure CVD (RPCVD), metal organic CVD (MOCVD), or the like. The epitaxial growth of the epitaxial layer 602 forms a surface 606 that replicates the upper surface 120 of the semiconductor surface and forms the facet 604. For example, the surface 606 of the epitaxial layer 602 may be a (100) plane when the upper surface 120 of the semiconductor substrate 102 is a (100) plane, and the facet 604 may be in a (111) plane. The facet 604 meets the curved surface of the cavity 404 at an intersection point 608. The curved surface (e.g., upper surface, ceiling) of the cavity 404 meeting the facet 604 arrests the facet 604 and prevents the facet 604 from further propagation. Hence, the surface 606 may continue to be replicated vertically in subsequent epitaxial growth without the facet 604 meeting and laterally limiting replication of the surface 606.

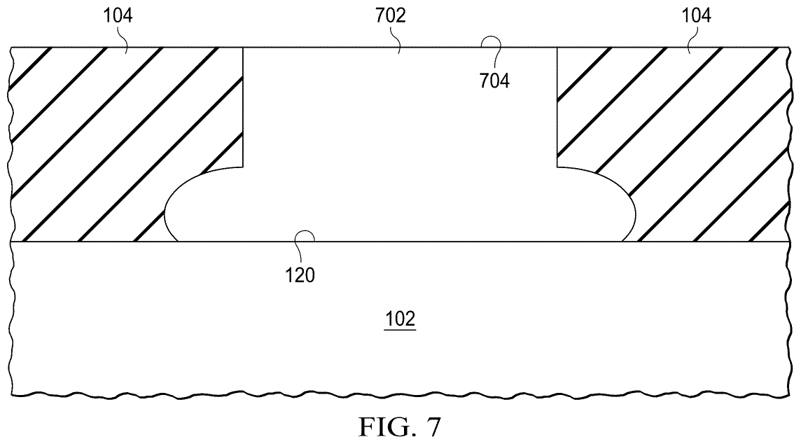

Referring to FIG. 7, epitaxial growth of the epitaxial layer 602 continues such that an epitaxial layer 702 is formed. The epitaxial layer 702 has a surface 704 that replicates the surface 606 in FIG. 6 and, hence, replicates the upper surface 120 of the semiconductor substrate 102. Although the cavities 404 are illustrated in FIG. 7 as being filled by the epitaxial layer 702, in some examples, a void may be formed in a cavity 404.

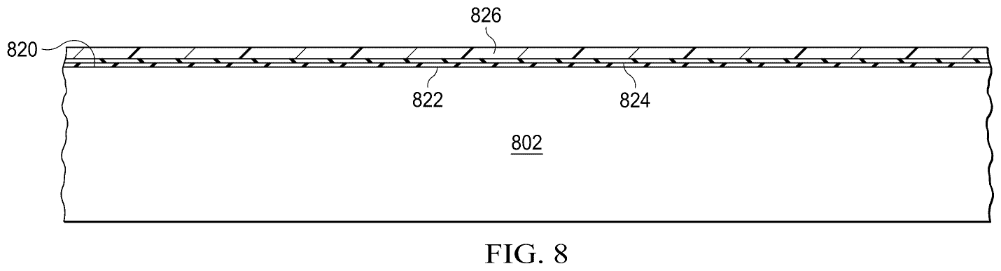

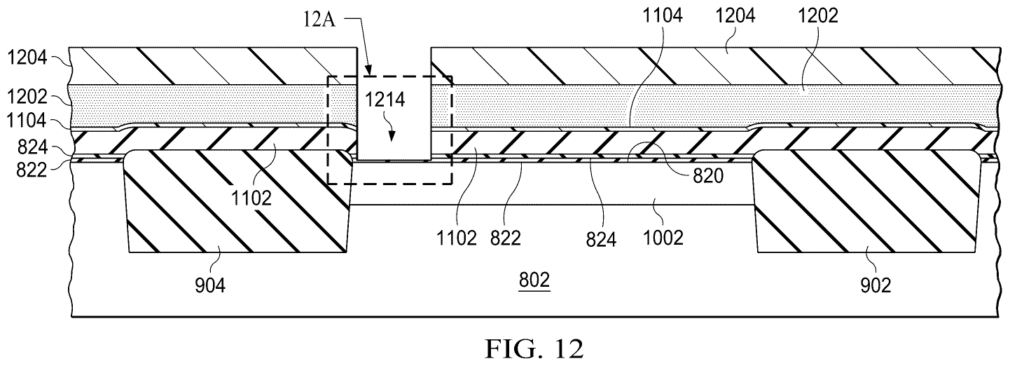

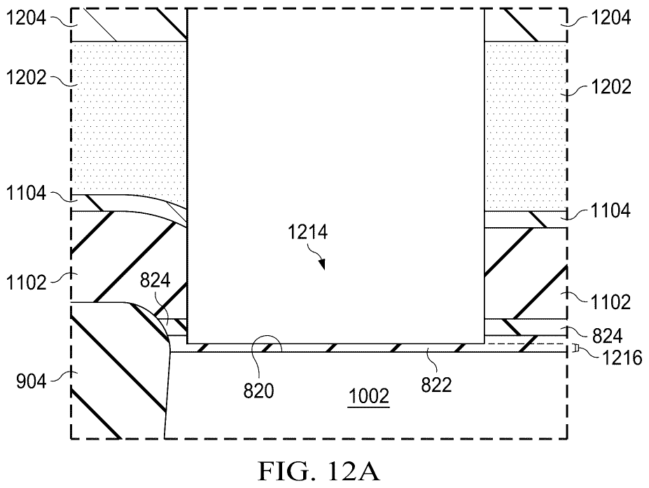

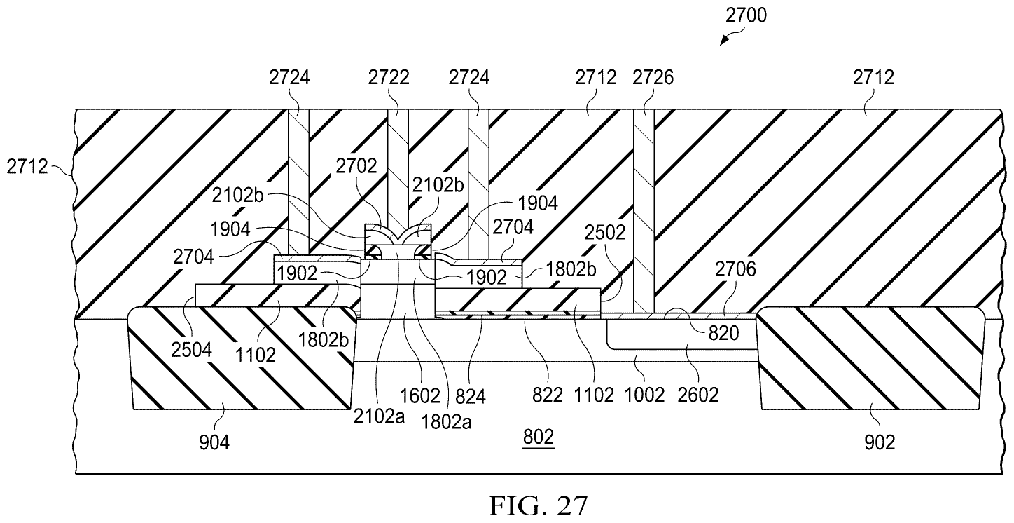

FIGS. 8 through 27 are respective cross-sectional views of a semiconductor device in intermediate stages of manufacturing according to some examples. The method illustrated in these figures forms the semiconductor device 2700 (e.g., a bipolar junction transistor (BJT)) of FIG. 27. FIGS. 12A, 13A, 14A, 15A, and 16A are expanded views of portions of the cross-sectional views of FIGS. 12, 13, 14, 15, and 16, respectively. The manufacturing method described above with respect to FIGS. 1 through 7 is implemented in the manufacturing illustrated in FIGS. 8 through 27 as referenced subsequently.

Referring to FIG. 8, a semiconductor substrate 802 is provided. The semiconductor substrate 802 is like the semiconductor substrate 102 of FIG. 1 described above. The semiconductor substrate 802 has an upper surface 820 in and/or on which devices (e.g., the BJT) are formed. In the illustrated example, the semiconductor material (e.g., silicon) of the semiconductor substrate 802 is p-type doped with a p-type dopant. In some examples, the semiconductor substrate 802 is p-type doped with a p-type dopant (e.g., boron (B)) with a concentration in a range from 1×10¹⁴ cm⁻³ to 1×10¹⁵ cm⁻³. Another dopant type and/or other doping concentrations may be implemented.

A first pedestal dielectric sub-layer 822 is formed over and on the upper surface 820 of the semiconductor substrate 802. In some examples, the first pedestal dielectric sub-layer 822 is or includes silicon oxide, which may be formed by ISSG oxidation. The first pedestal dielectric sub-layer 822 may also be, for example, a pad oxide layer. Another dielectric material and/or formation or deposition technique may be implemented.

A second pedestal dielectric sub-layer 824 is formed over and on the first pedestal dielectric sub-layer 822. In some examples, the second pedestal dielectric sub-layer 824 is or includes silicon oxide (e.g., a TEOS oxide), which may be deposited by CVD. In some examples, the second pedestal dielectric sub-layer 824 has an etch rate greater than the first pedestal dielectric sub-layer 822. Another dielectric material and/or formation or deposition technique may be implemented.

A hardmask layer 826 is formed over and on the second pedestal dielectric sub-layer 824. In some examples, the hardmask layer 826 is or includes silicon nitride, which may be deposited by CVD. Any dielectric material that may be selectively etched relative to the second pedestal dielectric sub-layer 824 and/or the first pedestal dielectric sub-layer 822 may be implemented for the hardmask layer 826, and any appropriate deposition process may be implemented to form the hardmask layer 826.

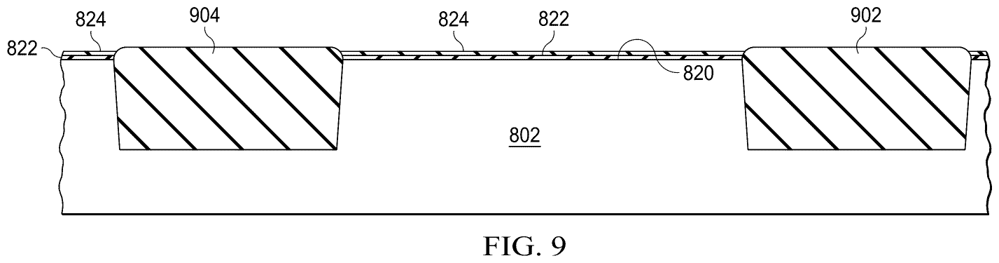

Referring to FIG. 9, isolation structures 902, 904 are formed in the semiconductor substrate 802. In the illustrated example, the isolation structures 902, 904 are shallow trench isolation structures (STIs) extending from the upper surface 820 of the semiconductor substrate 802 into the semiconductor substrate 802. As illustrated, the isolation structures 902, 904 are also through the first pedestal dielectric sub-layer 822 and the second pedestal dielectric sub-layer 824 and are raised above the upper surface 820 of the semiconductor substrate 802. The isolation structures 902, 904 may include, for example, a liner layer, such as including silicon oxide or silicon nitride, conformally along surfaces of a respective trench through the first pedestal dielectric sub-layer 822 and second pedestal dielectric sub-layer 824 and in the semiconductor substrate 802 and a fill isolation material, such as silicon oxide, over and on the liner layer.

To form the isolation structures 902, 904, trenches are formed through the first pedestal dielectric sub-layer 822 and second pedestal dielectric sub-layer 824 and in the semiconductor substrate 802. The trenches may be formed by patterning the hardmask layer 826, such as by using photolithography and an etching process (e.g., RIE). The trenches are etched, such as by RIE, through the first pedestal dielectric sub-layer 822 and second pedestal dielectric sub-layer 824 and in the semiconductor substrate 802 using the patterned hardmask layer 826 as a mask. The liner layer may then be conformally deposited in the recesses or trenches and over the patterned hardmask layer 826, such as by plasma enhanced CVD (PECVD) or formed on exposed surfaces of the recesses or trenches (e.g., by an oxidation process), and the fill isolation material may be deposited over the liner layer, such as by high aspect ratio CVD (HAR-CVD), flowable CVD (FCVD), or the like. Excess fill isolation material and liner layer may be removed from over the hardmask layer 826 by a planarization process, such as a chemical mechanical polish (CMP). The hardmask layer 826 may then be removed by an etch selective to the hardmask layer 826, which may be a wet etch process. In other examples, the isolation structures 902, 904 may be field oxide structures, such as local oxidation of silicon (LOCOS) structures, at the upper surface 820 of the semiconductor substrate 802, which may be formed using a LOCOS process.

The isolation structures 902, 904 laterally defines an area (e.g., an active area) of the upper surface 820 of the semiconductor substrate 802 on which the BJT is to be formed. The isolation structures 902, 904 together laterally encircle or encompass the active area of the upper surface 820 of the semiconductor substrate 802 on which the BJT is to be formed. As indicated subsequently, an active portion (e.g., a base layer) of the BJT extends laterally beyond the active area of the upper surface 820 of the semiconductor substrate 802 on which the BJT is formed and over the isolation structure 904.

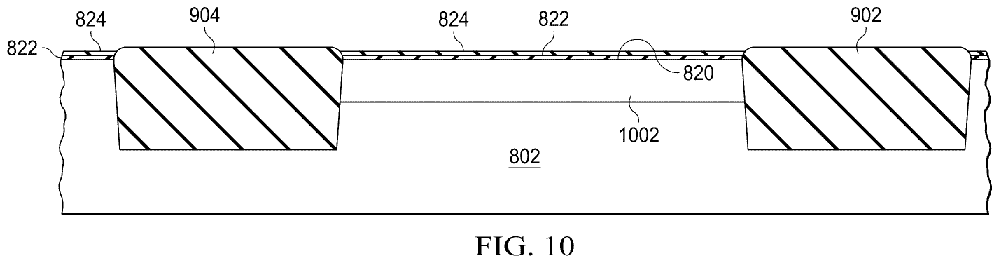

Referring to FIG. 10, an n-type doped sub-collector diffusion region 1002 is formed in the semiconductor substrate 802 laterally between the isolation structures 902, 904. The n-type doped sub-collector diffusion region 1002 may be formed by masking (e.g., by a photoresist using photolithography) areas of the semiconductor substrate 802 where an n-type doped sub-collector diffusion region is not to be formed and implanting n-type dopants into the semiconductor substrate 802. The n-type doped sub-collector diffusion region 1002 extends from the upper surface 820 of the semiconductor substrate 802 into a depth in the semiconductor substrate 802 and is laterally between the isolation structures 902, 904. A concentration of the n-type doped sub-collector diffusion region 1002 is greater than a concentration of the p-type dopant of the semiconductor substrate 802. In some examples, the n-type doped sub-collector diffusion region 1002 is doped with an n-type dopant with a concentration in a range from 1×10¹⁸ cm⁻³ to 1×10²⁰ cm⁻³. Another dopant and/or other doping concentrations may be implemented.

Although the semiconductor substrate 802 and n-type doped sub-collector diffusion region 1002 are described herein as being doped with a certain dopant conductivity type, such components may be doped with an opposite conductivity type (e.g., being n-type doped instead of p-type doped, and vice versa) in other examples. Similarly, subsequently described components that are described as being doped with a certain dopant conductivity type may also be doped with an opposite conductivity type in other examples.

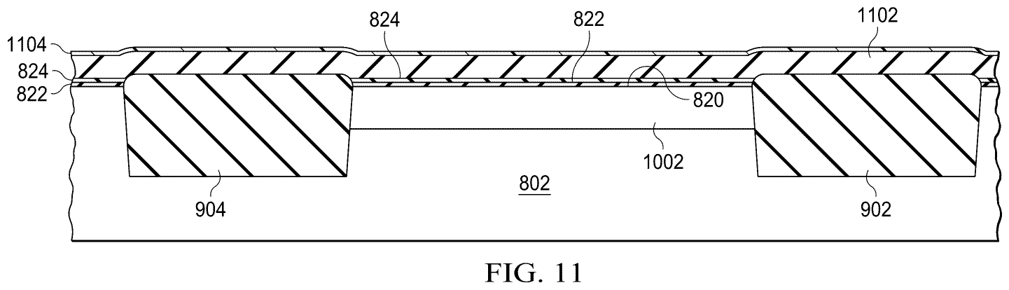

Referring to FIG. 11, a third pedestal dielectric sub-layer 1102 is formed over the second pedestal dielectric sub-layer 824 and the isolation structures 902, 904, and a hardmask layer 1104 is formed conformally over the third pedestal dielectric sub-layer 1102. The pedestal dielectric sub-layers 822, 824, 1102 form a pedestal dielectric structure that is pattered in subsequent processing. In some examples, the third pedestal dielectric sub-layer 1102 is silicon oxide (e.g., a TEOS oxide) deposited by CVD, although other dielectric materials and/or other deposition processes may be used in other examples. In some examples, the third pedestal dielectric sub-layer 1102 has an etch rate greater than the first pedestal dielectric sub-layer 822. In some examples, the third pedestal dielectric sub-layer 1102 has an etch rate greater than or equal to the second pedestal dielectric sub-layer 824. In some examples, the hardmask layer 1104 is or includes silicon nitride deposited by CVD, although other hardmask (e.g., dielectric) materials and/or other deposition processes may be used in other examples.

Referring to FIGS. 12 and 12A, an anti-reflection coating (ARC) layer 1202 is formed over the hardmask layer 1104, and a patterned photoresist 1204 is formed over the ARC layer 1202. The ARC layer 1202 may be or include an inorganic hardmask material used in, e.g., a tri-layer patterning scheme or the like. The ARC layer 1202 may be formed by using a spin-on coating process or the like. The photoresist 1204 is deposited (e.g., by spin-on) on or over the ARC layer 1202 and patterned using photolithography. The photoresist 1204 is patterned (e.g., using photolithography) to have an opening corresponding to a collector opening that is to be formed.

Using the patterned photoresist 1204 as a mask, an etch process is performed to remove portions of the ARC layer 1202, the hardmask layer 1104, the third pedestal dielectric sub-layer 1102, the second pedestal dielectric sub-layer 824, and the first pedestal dielectric sub-layer 822 to form a recess 1214. The recess 1214 generally laterally corresponds to a collector opening that is to be formed. The etch process may be as described above with respect to FIG. 2. A portion 1216 of the first pedestal dielectric sub-layer 822 remains underlying the recess 1214 and between the recess 1214 and the upper surface 820 of the semiconductor substrate 802. The recess 1214 in FIGS. 12 and 12A generally corresponds to the recess 204 of FIG. 2. Similarly, the dielectric layer 104 of FIG. 2 may be or include the first pedestal dielectric sub-layer 822, may be or include the pedestal dielectric sub-layers 822, 824, or may be or include the pedestal dielectric sub-layers 822, 824, 1102.

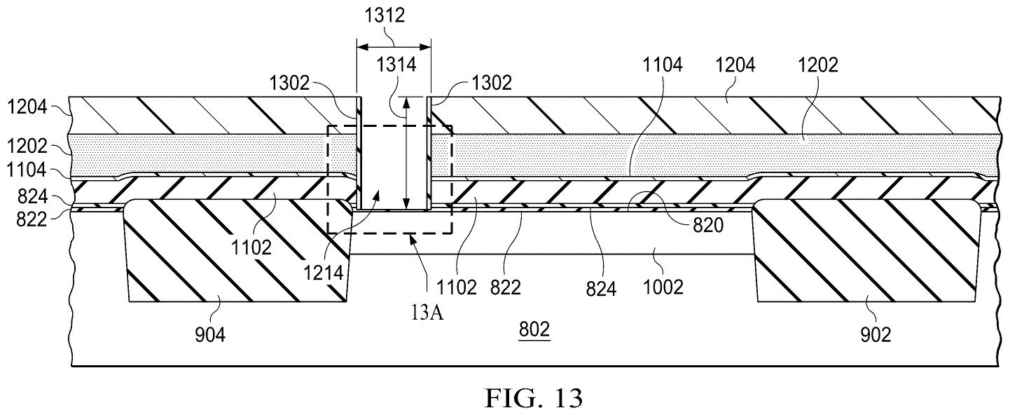

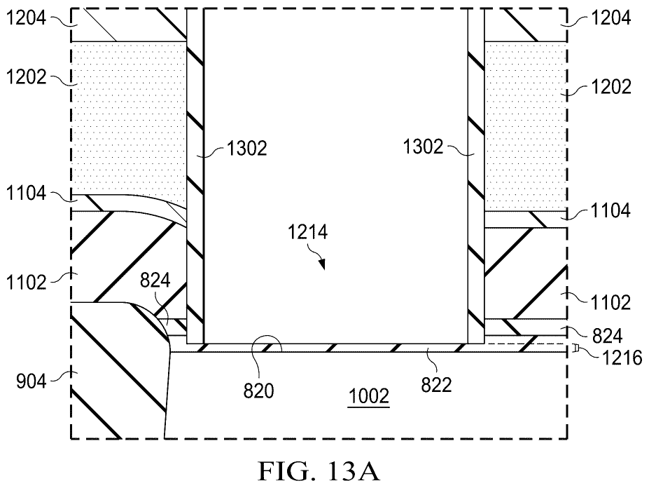

Referring to FIGS. 13 and 13A, sidewall etch stop liners 1302 are formed along respective sidewalls of the recess 1214. The sidewall etch stop liners 1302 are formed along sidewalls of the pedestal dielectric sub-layers 822, 824, 1102, the hardmask layer 1104, the ARC layer 1202, and the photoresist 1204. The sidewall etch stop liners 1302 may be formed as described above with respect to the sidewall etch stop liners 302 in FIG. 3. Like described above, in some examples, an aspect ratio of the combined recess 1214 through the corresponding opening through the photoresist 1204 may be a sufficient size to prevent a polymer liner from being deposited on the bottom surface of the recess 1214 while allowing sufficient coverage of the polymer liners along the sidewalls of the recess 1214. The aspect ratio, in this example, is a ratio of a lateral width 1312 of the recess 1214 (which corresponds to the width of the opening through the photoresist 1204) to the vertical depth 1314 from a top surface of the photoresist 1204 to the bottom surface of the recess 1214. A thickness of the ARC layer 1202 and/or the photoresist 1204 may be tuned to achieve a target aspect ratio. In other examples, a subsequent anisotropic etch may be performed when a liner is deposited on the bottom surface of the recess 1214.

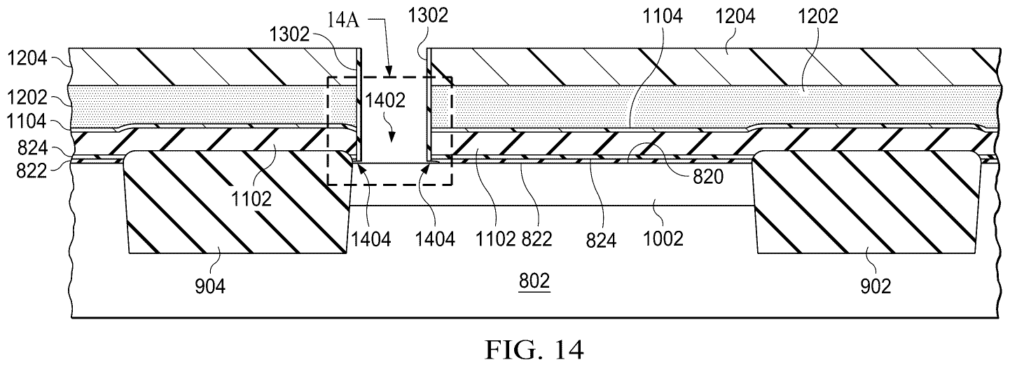

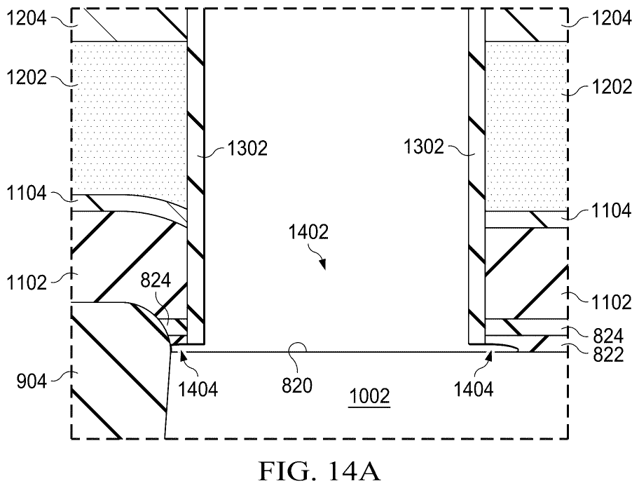

Referring to FIGS. 14 and 14A, an etch is performed to remove the remaining portion 1216 of the first pedestal dielectric sub-layer 822 and to undercut in the first pedestal dielectric sub-layer 822 under the sidewall etch stop liners 1302. The etch is as described above with respect to FIG. 4. The sidewall etch stop liners 1302 prevent the sidewalls of the pedestal dielectric sub-layers 822, 824, 1102 from being etched where the sidewall etch stop liners 1302 cover the sidewalls. The etch removes the remaining portion 1216 of the first pedestal dielectric sub-layer 822 from the bottom surface of the recess 1214 to expose the upper surface 820 of the semiconductor substrate 802. As the etch is performed, cavities 1404 are isotropically formed in the first pedestal dielectric sub-layer 822 undercutting the sidewall etch stop liners 1302. The cavities 1404 are formed to and expose the upper surface 820 of the semiconductor substrate 802. The etch forms an opening 1402 through the pedestal dielectric structure (e.g., the pedestal dielectric sub-layers 822, 824, 1102), and the opening 1402 is laterally defined by the sidewall etch stop liners 1302 and cavities 1404. The cavities 1404 of FIGS. 14 and 14A are like the cavities 404 of FIG. 4.

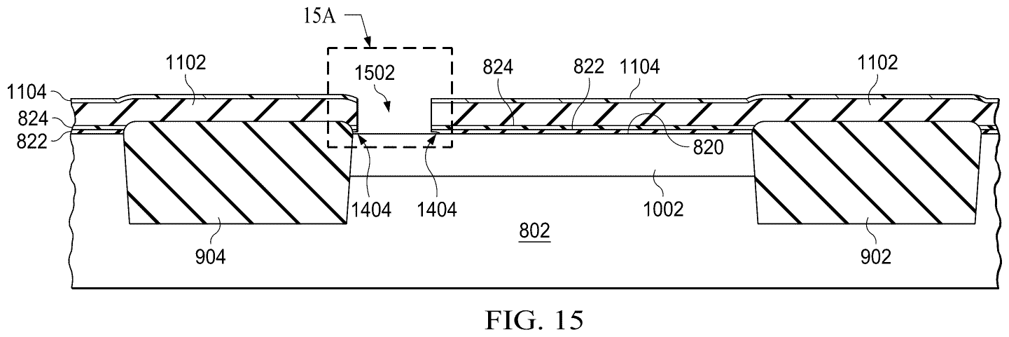

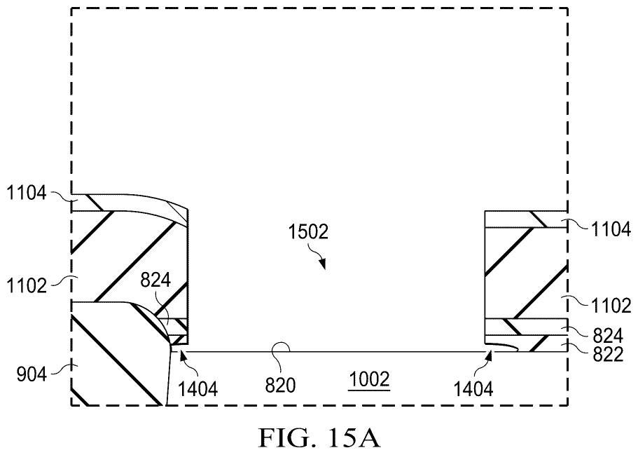

Referring to FIGS. 15 and 15A, the photoresist 1204, the ARC layer 1202, and the sidewall etch stop liners 1302 are removed. The removal of the photoresist 1204, the ARC layer 1202, and the sidewall etch stop liners 1302 result in a collector opening 1502 through the hardmask layer 1104 and the pedestal dielectric structure (e.g., the pedestal dielectric sub-layers 822, 824, 1102). The collector opening 1502 is defined by sidewalls of the hardmask layer 1104 and the pedestal dielectric structure (e.g., the pedestal dielectric sub-layers 822, 824, 1102) and curved surfaces of the cavities 1404 in the first pedestal dielectric sub-layer 822. The upper surface 820 of the semiconductor substrate 802 is exposed through the collector opening 1502. The collector opening 1502 generally extends from proximate to (or some lateral distance from) the isolation structure 904 laterally away from the isolation structure 904. In some examples, such as where the sidewall etch stop liners 1302 are polymer liners, the photoresist 1204, the ARC layer 1202, and the sidewall etch stop liners 1302 may be removed by a SPM followed by a SC1. Any appropriate wet process may be performed to remove the photoresist 1204, the ARC layer 1202, and the sidewall etch stop liners 1302 in other examples.

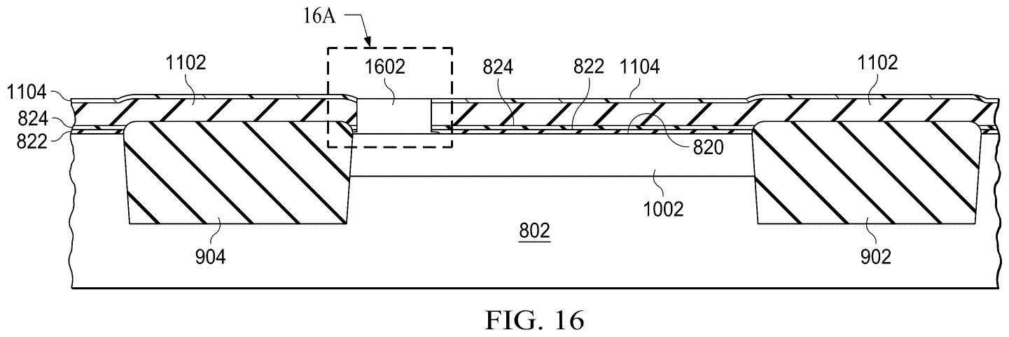

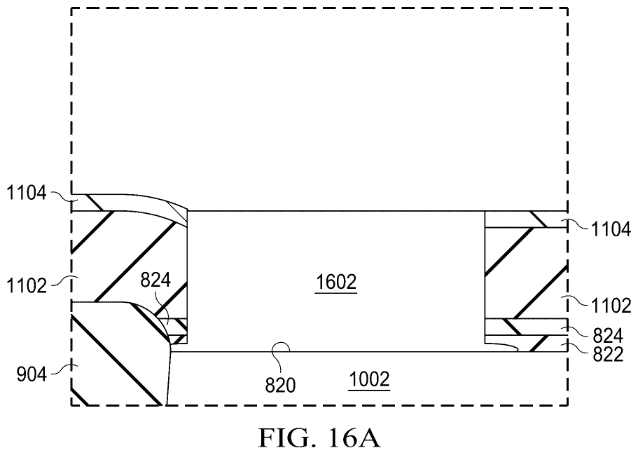

Referring to FIGS. 16 and 16A, a collector layer 1602 is formed over (e.g., on) the upper surface 820 of the semiconductor substrate 802 and in the collector opening 1502. In some examples, the collector layer 1602 is or includes a semiconductor layer doped with an n-type dopant (e.g., a same dopant type as the n-type doped sub-collector diffusion region 1002). In some examples, the collector layer 1602 is or includes silicon. In some examples, the collector layer 1602 is doped with an n-type dopant with a concentration in a range from 1×10¹⁹ cm⁻³ to 1×10²¹ cm⁻³. The collector layer 1602 may be epitaxially grown on the upper surface 820 of the semiconductor substrate 802 like described above with respect to the epitaxial layer 602, 702 in FIGS. 6 and 7. Like described above with respect to FIG. 6, the epitaxial growth of the collector layer 1602 forms an upper surface that replicates the upper surface 820 of the semiconductor surface and may form a facet. For example, the upper surface of the collector layer 1602 may be a (100) plane when the upper surface 820 of the semiconductor substrate 802 is a (100) plane, and the facet may be in a (111) plane. The facet may meet the curved surface of the cavity 1404 at an intersection point, and the curved surface of the cavity 1404 meeting the facet arrests the facet and prevents the facet from propagating in subsequent epitaxial growth. Hence, the upper surface of the collector layer 1602 may continue to be replicated vertically in subsequent epitaxial growth without the facet meeting and laterally limiting replication of the upper surface. The collector layer 1602 may be epitaxially grown by a selective epitaxial growth process in some examples. The epitaxial growth of the collector layer 1602 on the upper surface 820 of the semiconductor substrate 802 may result in the collector layer 1602 being monocrystalline. Further, the collector layer 1602 may be in situ doped during the epitaxial growth process (e.g., the selective epitaxial growth process). The epitaxial growth process may be a CVD process, such as an LPCVD, RPCVD, MOCVD, or the like. Other materials, dopant type, dopant concentration, and/or deposition process may be implemented.

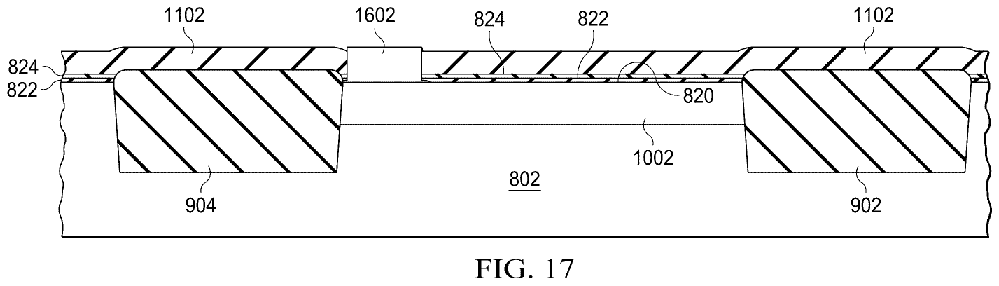

Referring to FIG. 17, the hardmask layer 1104 is removed. The hardmask layer 1104 may be removed using an etch selective to the material of the hardmask layer 1104. The etch process may be a wet or dry etch process and may be isotropic. For example, when the hardmask layer 1104 is silicon nitride, the etch process may be or include using phosphoric acid.

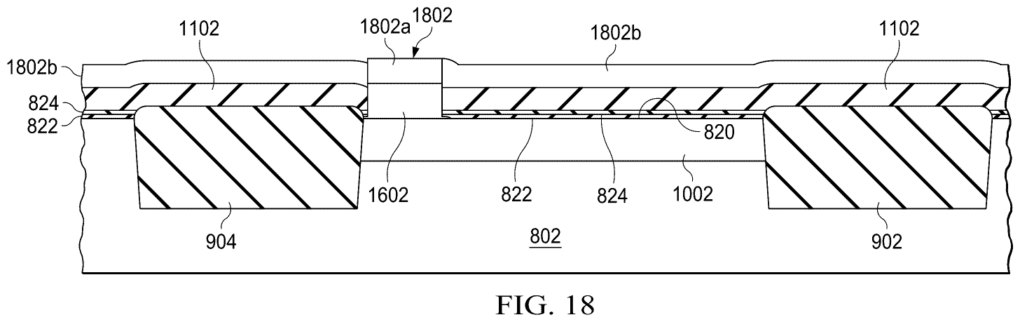

Referring to FIG. 18, a base layer 1802 is formed over the collector layer 1602. The base layer 1802 includes a monocrystalline base layer 1802a and a polycrystalline base layer 1802b. The monocrystalline base layer 1802a and polycrystalline base layer 1802b together form the base layer 1802. In some examples, the base layer 1802 is or includes a semiconductor layer doped with a p-type dopant (e.g., an opposite dopant type as the collector layer 1602). In some examples, the base layer 1802 is or includes silicon germanium. In some examples, the base layer 1802 is doped with a p-type dopant with a concentration in a range from 1×10¹⁷ cm⁻³ to 1×10²¹ cm⁻³. The base layer 1802 may also be doped with carbon (C) to prevent or reduce diffusion of the p-type dopant. The base layer 1802 may be epitaxially grown on the collector layer 1602 and conformally on the third pedestal dielectric sub-layer 1102. The base layer 1802 may be epitaxially grown by a non-selective epitaxial growth process in some examples. The non-selective epitaxial growth process grows the monocrystalline base layer 1802a from the collector layer 1602 and grows the polycrystalline base layer 1802b on other amorphous or polycrystalline surfaces, such as the third pedestal dielectric sub-layer 1102. The monocrystalline base layer 1802a may meet the polycrystalline base layer 1802b at a facet that is not specifically illustrated. The non-selective deposition of the base layer 1802 forms the base layer 1802 conformally. The base layer 1802 may be in situ doped during the epitaxial growth process. The base layer 1802 (e.g., the monocrystalline base layer 1802a and polycrystalline base layer 1802b each) may further include multiple sub-layers, such as a nucleation sub-layer of the same material as the collector layer 1602, an undoped sub-layer, a doped sub-layer, and a cap sub-layer of the same material of the emitter layer (described subsequently). The epitaxial growth process may be a CVD process, such as LPCVD, RPCVD, MOCVD, or the like. Other materials, dopant type, dopant concentration, and/or deposition process may be implemented.

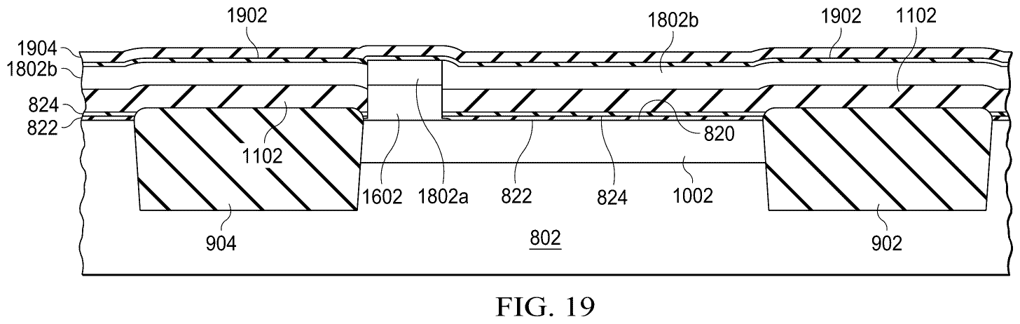

Referring to FIG. 19, a first dielectric spacer layer 1902 is formed conformally over the base layer 1802, and a second dielectric spacer layer 1904 is formed conformally over the first dielectric spacer layer 1902. In some examples, the second dielectric spacer layer 1904 is a dielectric material different from the dielectric material of the first dielectric spacer layer 1902. In some examples, the first dielectric spacer layer 1902 is silicon oxide (e.g., a TEOS oxide), and the second dielectric spacer layer 1904 is silicon nitride. The dielectric spacer layers 1902, 1904 may be deposited by CVD. Other dielectric materials and/or other deposition processes may be used in other examples.

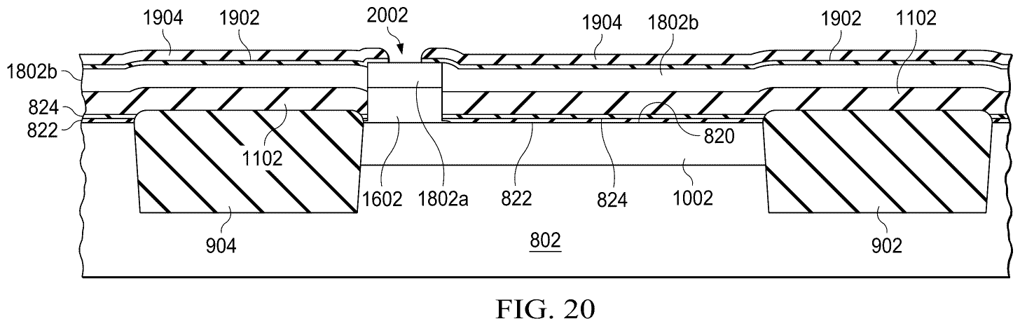

Referring to FIG. 20, the dielectric spacer layers 1902, 1904 are etched to form an emitter opening 2002 through the first dielectric spacer layer 1902 and the second dielectric spacer layer 1904. The monocrystalline base layer 1802a (of the base layer 1802) is exposed through the emitter opening 2002. The dielectric spacer layers 1902, 1904 may be patterned using appropriate photolithography and etch (e.g., RIE) processes.

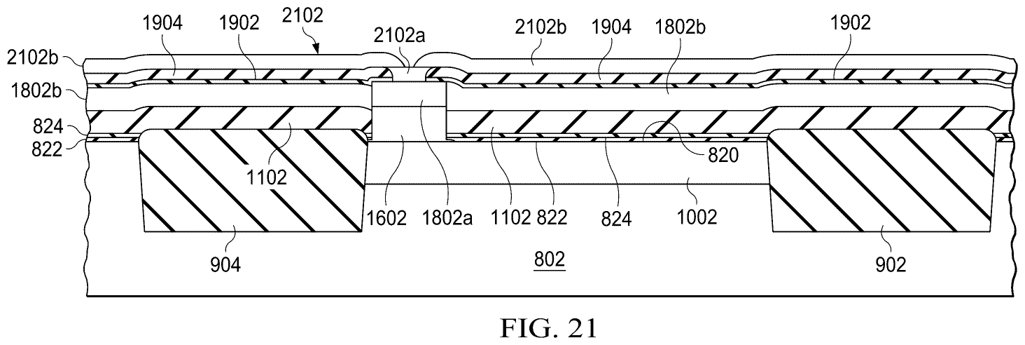

Referring to FIG. 21, an emitter layer 2102 is formed over the base layer 1802 (e.g., on the monocrystalline base layer 1802a). The emitter layer 2102 includes a monocrystalline emitter layer 2102a and a polycrystalline emitter layer 2102b. The monocrystalline emitter layer 2102a and polycrystalline emitter layer 2102b together form the emitter layer 2102. In some examples, the emitter layer 2102 is or includes a semiconductor layer doped with an n-type dopant (e.g., an opposite dopant type from the base layer 1802). In some examples, the emitter layer 2102 is or includes silicon. In some examples, the emitter layer 2102 is doped with an n-type dopant with a concentration in a range from 1×10¹⁹ cm⁻³ to 1×10²¹ cm⁻³. The emitter layer 2102 may be epitaxially grown on the base layer 1802 (e.g., the monocrystalline base layer 1802a) exposed through the emitter opening 2002 and on the second dielectric spacer layer 1904. The emitter layer 2102 may be epitaxially grown by a non-selective epitaxial growth process in some examples. The non-selective epitaxial growth process grows the monocrystalline emitter layer 2102a from the monocrystalline base layer 1802a and grows the polycrystalline emitter layer 2102b on other amorphous or polycrystalline surfaces, such as the second dielectric spacer layer 1904. The monocrystalline emitter layer 2102a may meet the polycrystalline emitter layer 2102b at a facet that is not specifically illustrated. The non-selective deposition of the emitter layer 2102 forms the emitter layer 2102 conformally. The emitter layer 2102 may be in situ doped during the epitaxial growth process. The epitaxial growth process may be a CVD process, such as LPCVD, RPCVD, MOCVD, or the like. Other materials, dopant type, dopant concentration, and/or deposition process may be implemented.

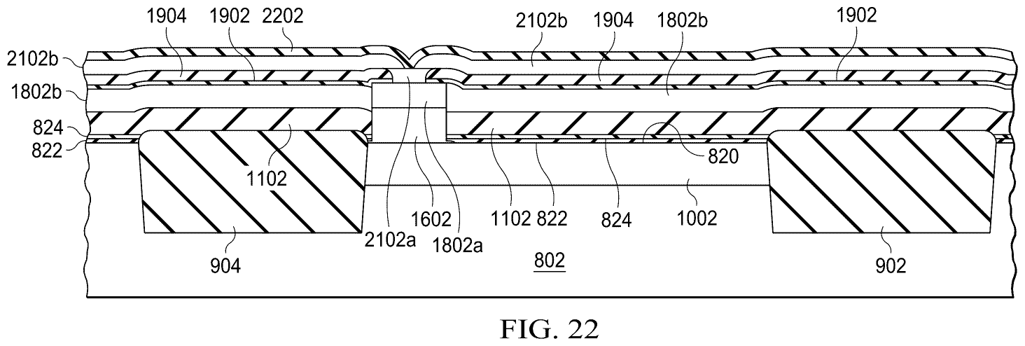

Referring to FIG. 22, an emitter dielectric cap layer 2202 is conformally formed over the emitter layer 2102. In some examples, the emitter dielectric cap layer 2202 is silicon oxide (e.g., a TEOS oxide) deposited by CVD, although other dielectric materials and/or other deposition processes may be used in other examples.

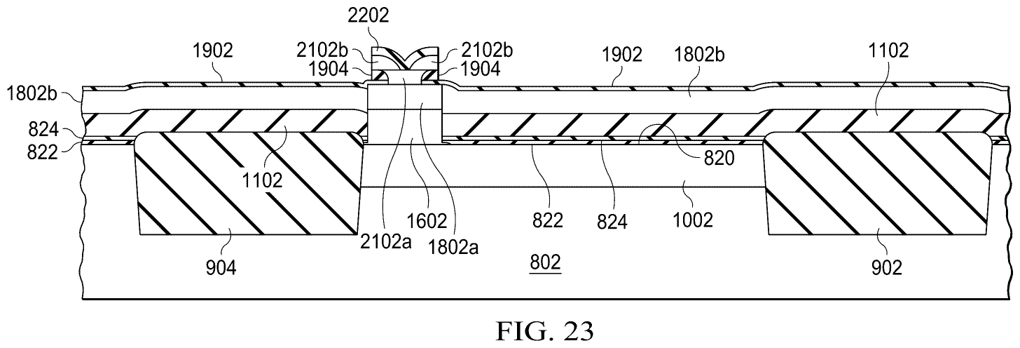

Referring to FIG. 23, the emitter dielectric cap layer 2202, polycrystalline emitter layer 2102b, and second dielectric spacer layer 1904 are patterned. In the illustrated example, the layers 2202, 2102b, 1904 are patterned using appropriate photolithography and etch (e.g., anisotropic etch, such as RIE) processes.

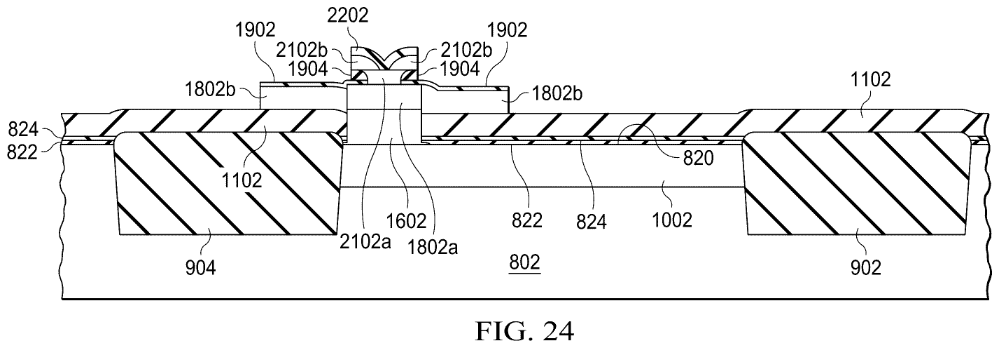

Referring to FIG. 24, the first dielectric spacer layer 1902 and the base layer 1802 (e.g., the polycrystalline base layer 1802b) are patterned. In some examples, the third pedestal dielectric sub-layer 1102 may be thinned in areas where the first dielectric spacer layer 1902 and the polycrystalline base layer 1802b are removed. The first dielectric spacer layer 1902 and the polycrystalline base layer 1802b may be patterned using appropriate photolithography and etch (e.g., RIE) processes.

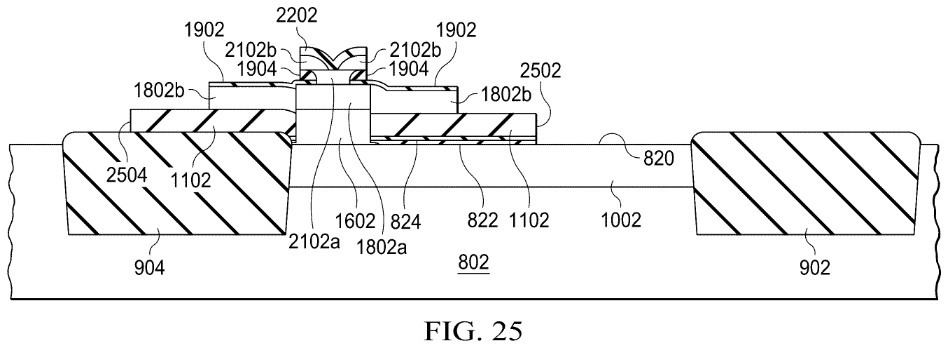

Referring to FIG. 25, the third pedestal dielectric sub-layer 1102, the second pedestal dielectric sub-layer 824, and the first pedestal dielectric sub-layer 822 are patterned. Patterning the pedestal dielectric sub-layers 822, 824, 1102 forms the pedestal dielectric structure (e.g., the third pedestal dielectric sub-layer 1102) with sidewalls 2502, 2504. The sidewall 2502 of the pedestal dielectric structure (e.g., the pedestal dielectric sub-layers 822, 824, 1102) is over the upper surface 820 of the semiconductor substrate 802 and the n-type doped sub-collector diffusion region 1002. The sidewall 2504 of the pedestal dielectric structure (e.g., the third pedestal dielectric sub-layer 1102) is over the isolation structure 904. Portions of the pedestal dielectric sub-layers 822, 824, 1102 are removed from over at least a portion of the n-type doped sub-collector diffusion region 1002. The pedestal dielectric sub-layers 822, 824, 1102 may be patterned using appropriate photolithography and etch (e.g., RIE) processes.

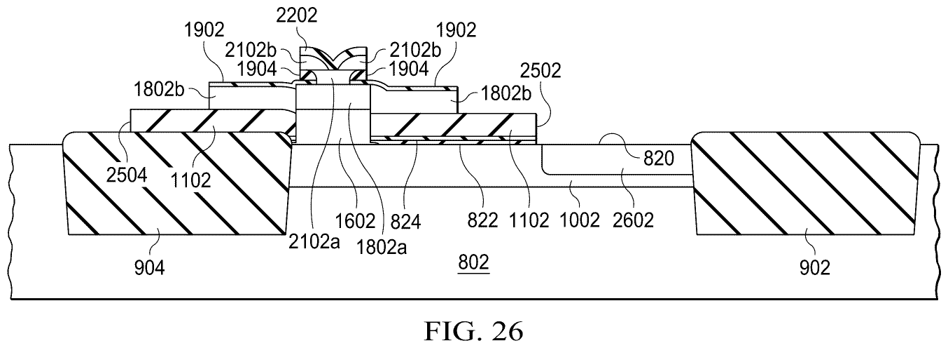

Referring to FIG. 26, an n-type collector contact region 2602 is formed in the semiconductor substrate 802. The n-type collector contact region 2602 is formed in the n-type doped sub-collector diffusion region 1002 in the semiconductor substrate 802. The n-type collector contact region 2602 is laterally between the pedestal dielectric structure (e.g., the pedestal dielectric sub-layers 822, 824, 1102) and the isolation structure 902. An implantation is performed to form the n-type collector contact region 2602. The n-type collector contact region 2602 may be formed by masking (e.g., by a photoresist using photolithography) the base layer 1802 and emitter layer 2102 and implanting an n-type dopant into the semiconductor substrate 802 in an exposed portion of the semiconductor substrate 802 corresponding to the n-type collector contact region 2602. A concentration of the n-type dopant of the n-type collector contact region 2602 is greater than the concentration of the n-type dopant of the n-type doped sub-collector diffusion region 1002. In some examples, the n-type collector contact region 2602 is doped with an n-type dopant with a concentration in a range from 1×1020 cm-3 to 1×1021 cm-3. Other doping concentrations may be implemented.

Referring to FIG. 27, metal-semiconductor compound 2702, 2704, 2706 are formed. The metal-semiconductor compound 2702 is on the emitter layer 2102 (e.g., the polycrystalline emitter layer 2102b and/or monocrystalline emitter layer 2102a). The metal-semiconductor compound 2704 is on the base layer 1802 (e.g., the polycrystalline base layer 1802b). The metal-semiconductor compound 2706 is on the upper surface 820 of the semiconductor substrate 802 at the n-type collector contact region 2602. The metal-semiconductor compound 2702, 2704, 2706 may be a silicide (e.g., NiSix, TiSix, CoSix, PtSix), a germanicide, or the like.

To form the metal-semiconductor compound 2702, 2704, 2706, any remaining dielectric material on surfaces on which the metal-semiconductor compound 2702, 2704, 2706 are to be formed is removed. For example, the emitter dielectric cap layer 2202 and exposed portions of the first dielectric spacer layer 1902 may be removed by an etch and/or cleaning process. For example, when the emitter dielectric cap layer 2202 and the first dielectric spacer layer 1902 are silicon oxide, dilute hydrochloric acid (dHCl) may be used. The first dielectric spacer layer 1902 underlying the second dielectric spacer layer 1904 remains after the exposed portions of the first dielectric spacer layer 1902 are removed. Other layers may be thinned by the etch and/or cleaning process. For example, exposed portions of the third pedestal dielectric sub-layer 1102 may be thinned.

The metal-semiconductor compound 2702, 2704, 2706 may then be formed by depositing a metal (e.g., Ni, Ti, Co, Pt) over the semiconductor substrate 802, such as by physical vapor deposition (PVD), CVD, or the like. The metal is reacted with a semiconductor material, such as the semiconductor material of the emitter layer 2102 (e.g., polycrystalline emitter layer 2102b and/or monocrystalline emitter layer 2102a), the semiconductor material of the base layer 1802 (e.g., the polycrystalline base layer 1802b and/or monocrystalline base layer 1802a), and the semiconductor material of the semiconductor substrate 802. An anneal process may be used to cause the metal to react with a semiconductor material. For example, a laser anneal (e.g., a millisecond laser anneal) may be used in a reduced thermal budget implementation. Any unreacted metal may be removed, such as by an etch selective to the metal.

After forming the metal-semiconductor compound 2702, 2704, 2706, a dielectric layer 2712 is formed over the semiconductor substrate 802, and contacts 2722, 2724, 2726 are formed through the dielectric layer 2712. The dielectric layer 2712 may include one or more dielectric sub-layers. For example, the dielectric layer 2712 may include a conformal first dielectric sub-layer over the semiconductor substrate 802 and a second dielectric sub-layer over the first dielectric sub-layer. The conformal first dielectric sub-layer may be a stressor layer, an etch stop layer, or the like, which may be or include silicon nitride, silicon oxynitride, the like, or a combination thereof. The second dielectric sub-layer may be or include silicon oxide, silicon nitride, or the like. The dielectric layer 2712 may be or include a pre-metal dielectric (PMD), an inter-layer dielectric (ILD), or the like. The dielectric layer 2712 may be deposited using CVD, PECVD, ALD, or the like. The dielectric layer 2712 may be planarized, such as by a CMP.

The contacts 2722, 2724, 2726 extend through the dielectric layer 2712 and contact respective metal-semiconductor compound 2702, 2704, 2706. The contacts 2722, 2724, 2726 may each include one or more barrier and/or adhesion layers (e.g., titanium nitride (TiN), tantalum nitride (TaN), the like, or a combination thereof) conformally in a respective opening through the dielectric layer 2712, and a fill metal (e.g., tungsten (W), copper (Cu), aluminum (Al), the like, or a combination thereof) over and/or on the barrier and/or adhesion layer(s). To form the contacts 2722, 2724, 2726, respective openings may be formed through the dielectric layer 2712 to the metal-semiconductor compound 2702, 2704, 2706 using appropriate photolithography and etching processes. A metal(s) of the contacts 2722, 2724, 2726 are deposited in the openings through the dielectric layer 2712. The metal(s) may be deposited using an appropriate deposition process(es), such as CVD, PVD, or the like. Any excess metal(s) may be removed, such as by a CMP and/or by patterning using photolithography and etch processes.

FIG. 27 illustrates a semiconductor device 2700. The semiconductor device 2700 is or includes a BJT. The BJT includes the collector layer 1602, base layer 1802 (e.g., monocrystalline base layer 1802a and polycrystalline base layer 1802b), and emitter layer 2102 (e.g., monocrystalline emitter layer 2102a and polycrystalline emitter layer 2102b).

The collector layer 1602 is over and on the upper surface 820 of the semiconductor substrate 802 and is through an opening in a pedestal dielectric structure (e.g., the third pedestal dielectric sub-layer 1102, second pedestal dielectric sub-layer 824, and first pedestal dielectric sub-layer 822), which is also over the upper surface 820 of the semiconductor substrate 802. The collector layer 1602 is on the n-type doped sub-collector diffusion region 1002 in the semiconductor substrate 802. The base layer 1802 (e.g., the monocrystalline base layer 1802a) is over and on the collector layer 1602, and the base layer 1802 (e.g., the polycrystalline base layer 1802b) is over and on an upper surface of the pedestal dielectric structure (e.g., the third pedestal dielectric sub-layer 1102).

The pedestal dielectric structure (e.g., the pedestal dielectric sub-layers 822, 824, 1102) underlies the base layer 1802. The pedestal dielectric structure extends laterally from the base layer 1802 (e.g., the polycrystalline base layer 1802b). For example, the pedestal dielectric structure extends over and on the upper surface 820 of the semiconductor substrate 802 over the n-type doped sub-collector diffusion region 1002 and laterally away from a corresponding sidewall of the polycrystalline base layer 1802b to the sidewall 2502 proximate the n-type collector contact region 2602. Additionally, the pedestal dielectric structure (e.g., the third pedestal dielectric sub-layer 1102) extends over and on the isolation structure 904 laterally away from a corresponding sidewall of the polycrystalline base layer 1802b to the sidewall 2504 over the isolation structure 904.

The emitter layer 2102 (e.g., the monocrystalline emitter layer 2102a) is over and on the base layer 1802 (e.g., the monocrystalline base layer 1802a) and is through an opening defined by a spacer structure, and the emitter layer 2102 (e.g., the polycrystalline emitter layer 2102b) is over and on the spacer structure. The spacer structure includes the first dielectric spacer layer 1902 and the second dielectric spacer layer 1904.

The metal-semiconductor compound 2702 is on the emitter layer 2102 (e.g., the polycrystalline emitter layer 2102b and/or monocrystalline emitter layer 2102a). The metal-semiconductor compound 2704 is on the base layer 1802 (e.g., the polycrystalline base layer 1802b). The metal-semiconductor compound 2706 is on the upper surface 820 of the semiconductor substrate 802 on the n-type collector contact region 2602.

In some examples, the BJT may be a heterojunction BJT. As indicated previously, in some examples, the collector layer 1602 and the emitter layer 2102 may be silicon, and the base layer 1802 may include silicon germanium. Hence, in some examples, the base layer 1802 may include a semiconductor material dissimilar from respective semiconductor materials of the collector layer 1602 and emitter layer 2102. The dissimilar semiconductor materials may form one or more heterojunctions in the BJT, and the BJT may therefore be a heterojunction BJT.

Although various examples have been described in detail, it should be understood that various changes, substitutions, and alterations can be made therein without departing from the scope defined by the appended claims.

What is claimed is:

1. A semiconductor device, comprising:
a first semiconductor material comprising a monocrystalline surface;
a dielectric layer over the first semiconductor material, the dielectric layer having an opening to the monocrystalline surface, the opening being defined at least in part by a sidewall of the dielectric layer and a cavity in the dielectric layer, the cavity being at the monocrystalline surface and under the sidewall; and
a second semiconductor material over the first semiconductor material and on the monocrystalline surface, the second semiconductor material being at least partially in the opening through the dielectric layer, wherein the cavity in the dielectric layer is configured to trap a facet of the second semiconductor material in the cavity.

2. The semiconductor device of claim 1, further comprising a semiconductor substrate comprising the first semiconductor material, the dielectric layer being over the semiconductor substrate.

3. The semiconductor device of claim 1, wherein the dielectric layer comprises a first dielectric sub-layer and a second dielectric sub-layer, the first dielectric sub-layer being over the first semiconductor material, the second dielectric sub-layer being over the first dielectric sub-layer, the cavity being in the first dielectric sub-layer.

4. The semiconductor device of claim 1, wherein the cavity has a curved surface that meets the sidewall at a first intersection and meets the monocrystalline surface at a second intersection, a line through the first intersection and the second intersection forming an angle with the monocrystalline surface laterally interior to the opening, the angle being equal to or less than 54 degrees.

5. The semiconductor device of claim 1, wherein the cavity has a curved surface that meets the sidewall at a first intersection and meets the monocrystalline surface at a second intersection, a vertical dimension being vertically from the monocrystalline surface to the first intersection, a lateral dimension being laterally from the first intersection to the second intersection, a ratio of the vertical dimension to the lateral dimension being equal to or less than 1.376.

6. The semiconductor device of claim 1, wherein the cavity has a curved surface that meets the monocrystalline surface at an intersection, a lateral dimension being laterally from the sidewall to the intersection, the lateral dimension being equal to or greater than 10 nm.

7. The semiconductor device of claim 1, further comprising a bipolar junction transistor comprising:
a collector layer including the first semiconductor material;
a base layer on the collector layer; and
an emitter layer on the base layer.

8. A method, comprising:
forming a dielectric layer over a first semiconductor material, the first semiconductor material comprising a monocrystalline surface;
forming an opening through the dielectric layer to the monocrystalline surface, the opening being defined at least in part by a sidewall of the dielectric layer and a cavity in the dielectric layer, the cavity being at the monocrystalline surface and under the sidewall; and
forming a second semiconductor material over the first semiconductor material and on the monocrystalline surface, the second semiconductor material being at least partially in the opening through the dielectric layer, wherein the cavity in the dielectric layer is configured to trap a facet of the second semiconductor material in the cavity.

9. The method of claim 8, wherein forming the opening includes:
forming a recess in the dielectric layer, the recess being defined at least in part by the sidewall of the dielectric layer and a lateral surface of the dielectric layer; and
forming the cavity in the dielectric layer through the lateral surface of the dielectric layer, wherein forming the cavity exposes the monocrystalline surface through the opening.

10. The method of claim 8, wherein forming the cavity exposes a portion of the monocrystalline surface under the dielectric layer a lateral distance from the sidewall of the dielectric layer, the lateral distance being equal to or greater than 10 nm.

11. The method of claim 8, wherein forming the opening includes:
forming a recess in the dielectric layer, the recess being defined at least in part by the sidewall of the dielectric layer and a lateral surface of the dielectric layer;
forming a liner on the sidewall of the dielectric layer; and
forming the cavity in the dielectric layer through the lateral surface of the dielectric layer and under the liner on the sidewall of the dielectric layer.

12. The method of claim 11, wherein forming the cavity includes performing an isotropic etch selective to the dielectric layer, the isotropic etch etching the dielectric layer from the lateral surface of the dielectric layer to the monocrystalline surface and undercutting the liner into the dielectric layer.

13. The method of claim 11, wherein forming the liner includes:
depositing the liner on the sidewall of the dielectric layer; and
performing an anisotropic etch after depositing the liner.

14. The method of claim 11, wherein forming the liner includes depositing the liner on the sidewall of the dielectric layer without depositing a liner on the lateral surface of the dielectric layer.

15. The method of claim 11, further comprising removing the liner after forming the cavity.

16. The method of claim 8, wherein forming the second semiconductor material includes epitaxially growing the second semiconductor material on the monocrystalline surface.

17. The method of claim 16, wherein epitaxially growing the second semiconductor material on the monocrystalline surface forms the facet of the second semiconductor material, the facet being trapped in the cavity in the dielectric layer.

18. The method of claim 8, wherein the cavity has a surface that meets the sidewall at a first intersection and meets the monocrystalline surface at a second intersection, a line through the first intersection and the second intersection forming an angle with the monocrystalline surface laterally interior to the opening, the angle being equal to or less than 54 degrees.

19. The method of claim 8, wherein the cavity has a surface that meets the sidewall at a first intersection and meets the monocrystalline surface at a second intersection, a vertical dimension being vertically from the monocrystalline surface to the first intersection, a lateral dimension being laterally from the first intersection to the second intersection, a ratio of the vertical dimension to the lateral dimension being equal to or less than 1.376.

20. A semiconductor device, comprising:
a semiconductor substrate having an upper surface;
a pedestal dielectric structure over the semiconductor substrate, the pedestal dielectric structure having an opening to the upper surface of the semiconductor substrate, the opening being defined at least in part by a sidewall of the pedestal dielectric structure and a cavity in the pedestal dielectric structure, the cavity being at the upper surface and under the sidewall, wherein the cavity has a surface that meets the sidewall at a first intersection and meets the upper surface at a second intersection, a vertical dimension being vertically from the upper surface to the first intersection, a lateral dimension being laterally from the first intersection to the second intersection, a ratio of the vertical dimension to the lateral dimension being equal to or less than 1.376;
a collector layer on the upper surface of the semiconductor substrate and at least partially in the opening through the pedestal dielectric structure;
a base layer on the collector layer; and
an emitter layer on the base layer.

21. The semiconductor device of claim 20, wherein the pedestal dielectric structure comprises a first dielectric sub-layer and a second dielectric sub-layer, the first dielectric sub-layer being over the semiconductor substrate, the second dielectric sub-layer being over the first dielectric sub-layer, the cavity being in the first dielectric sub-layer.
